(19) United States
(12) Patent Application Publication
(10) Pub. No.: US 2008/0254642 A1
(43) Pub. Date: Oct. 16, 2008

(54) METHOD OF FABRICATING GATE DIELECTRIC LAYER

(75) Inventors: Yun-Ren Wang, Tainan (TW); Ying-Wei Yen, Miaoli County (TW); Chien-Liang Lin, Taoyuan County (TW); Shu-Yen Chan, Hsinchu County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/735,916

(22) Filed: Apr. 16, 2007

(51) Int. Cl. H01L 21/31

(52) U.S. Cl. 438/763; 257/E21.24

(57) ABSTRACT

A method for fabricating gate dielectric layer is provided. First, a sacrificial layer is formed on a substrate. Next, fluorine ions are implanted into the substrate. Then, the sacrificial layer is then removed. Finally, a dielectric layer is formed on the substrate.

### BACKGROUND OF THE INVENTION

1. Field of the Invention

The present invention generally relates to a method of fabricating a semiconductor device, more particular, to a method of fabricating a gate dielectric layer.

2. Description of Related Art

As the dimensions of metal-oxide-semiconductor (MOS) devices are reduced, there are more stringent demands on the quality of the gate dielectric layer including special interface characteristics for the gate dielectric layer and the substrate.

However, a large number of dangling bonds are formed on the silicon substrate. These dangling bond defects destabilize the interface between the gate dielectric layer and the substrate and lead to a higher threshold voltage. Furthermore, the reliability of the semiconductor device is lowered so that the life span of the semiconductor device is reduced.

In addition, the presence of dangling bonds in the interface between the gate dielectric layer and the substrate also causes some of the charge carriers to be trapped by the dangling bonds when a current is flowing between the source and the drain. Therefore, carrier mobility in the channel region is lowered and the conductive current between the source and the drain is reduced.

The conventional method of resolving the foregoing problem is to add hydrogen atoms into the substrate. The hydrogen atoms form covalent bonds with the silicon to eliminate the defects so that the goal achieving of higher carrier mobility can be realized. However, silicon-hydrogen bonds are low energy bonds. In a high-temperature environment or after the semiconductor device has been operating for a period of time, the number of silicon-hydrogen bonds will be reduced. At this time, the number of carriers being trapped by the defects will increase again.

### SUMMARY OF THE INVENTION

Accordingly, the present invention is directed to a method for fabricating a gate dielectric layer that can effectively reduce the number of dangling bonds at the interface between the gate dielectric layer and a substrate.

The present invention is directed to a method for fabricating the gate dielectric layer of a core device that can easily combine with existing semiconductor fabrication process.

According to an embodiment of the present invention, a method for fabricating a gate dielectric layer is provided. First, a sacrificial layer is formed on a substrate. Next, fluorine ions are implanted into the substrate. Then, the sacrificial layer is then removed. Finally, a dielectric layer is formed on the substrate.

According to the foregoing method for fabricating the gate dielectric layer in the embodiment of the present invention, the method of forming the sacrificial layer includes performing a thermal oxidation process.

According to the foregoing method for fabricating the gate dielectric layer in the embodiment of the present invention, the method of implanting fluorine ions in the substrate includes performing an ion implantation process.

According to the foregoing method for fabricating the gate dielectric layer in the embodiment of the present invention, the method of forming the dielectric layer includes performing a thermal oxidation process.

According to the foregoing method for fabricating the gate dielectric layer in the embodiment of the present invention, the method further includes performing a nitridation process on the dielectric layer after forming the dielectric layer on the substrate.

According to the foregoing method for fabricating the gate dielectric layer in the embodiment of the present invention, the method further includes performing an annealing process after performing the nitridation process.

The present invention also provides a method for fabricating the gate dielectric layer of a core device. First, a first dielectric layer to be used on a first input/output device is formed on a substrate. Next, a patterned mask layer is formed on the first dielectric layer. After that, fluorine ions are implanted into the substrate using the patterned mask layer as a mask. A portion of the first dielectric layer exposed by the patterned mask layer is removed so as to expose a portion of the substrate. Thereafter, the patterned mask layer is removed. Finally, a second dielectric layer is formed on the portion of the substrate.

According to the method for fabricating the gate dielectric layer of the core device in the embodiment of the present invention, the method of forming the first dielectric layer includes performing a thermal oxidation process.

According to the method for fabricating the gate dielectric layer of the core device in the embodiment of the present invention, the method of implanting fluorine ions into the substrate includes performing an ion implantation process.

According to the method for fabricating the gate dielectric layer of the core device in the embodiment of the present invention, the method of forming the second dielectric layer includes performing a thermal oxidation process.

According to the method for fabricating the gate dielectric layer of the core device in the embodiment of the present invention, the thickness of the second dielectric layer is smaller than that of the first dielectric layer.

According to the method for fabricating the gate dielectric layer of the core device in the embodiment of the present invention, the method further includes performing a nitridation process on the second dielectric layer after forming the second dielectric layer on the portion of the substrate.

According to the method for fabricating the gate dielectric layer of the core device in the embodiment of the present invention, the nitridation process includes a plasma nitridation process.

According to the method for fabricating the gate dielectric layer of the core device in the embodiment of the present invention, the method further includes performing an annealing process after performing the nitridation process on the second dielectric layer.

According to the method for fabricating the gate dielectric layer of the core device in the embodiment of the present invention, the method of removing the patterned mask layer includes performing a dry etching process.

According to the method for fabricating the gate dielectric layer of the core device in the embodiment of the present invention, the method further includes forming a patterned third dielectric layer on the substrate for the second input/output device before forming the first dielectric layer.

According to the method for fabricating the gate dielectric layer of the core device in the embodiment of the present invention, the method of forming the third patterned dielectric layer includes forming a third dielectric layer on the substrate and patterning the third dielectric layer.

According to the method for fabricating the gate dielectric layer of the core device in the embodiment of the present invention, the method of forming the third dielectric layer includes performing a thermal oxidation process.

According to the method for fabricating the gate dielectric layer of the core device in the embodiment of the present invention, the thickness of the first dielectric layer is smaller than that of the third dielectric layer, and the thickness of the second dielectric layer is smaller than that of the first dielectric layer.

Accordingly, in the method for fabricating the gate dielectric layer according to the present invention, fluorine ions capable of bonding with dangling silicon bonds are implanted into the substrate. As a result, the interface between the gate dielectric layer and the substrate is stabilized and the threshold voltage is lowered. Moreover, the reliability of the semiconductor device is improved and the life span of the semiconductor device is prolonged.

In addition, less dangling bonds are left for trapping the charge carriers because the dangling bonds are bonded to the fluorine ions. Consequently, the mobility of the carriers in the channel region is increased and hence the amount of current flowing between the source and the drain in the conductive state is enhanced.

On the other hand, the method for fabricating the dielectric layer of the core device is not so complicated to operate and can easily combine with existing semiconductor process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow diagram showing a method for fabricating a gate dielectric layer according to an embodiment of the present invention.

FIGS. 2A and 2B are schematic cross-sectional views showing the process of fabricating a gate dielectric layer according to an embodiment of the present invention.

FIG. 3 is a flow diagram showing a method of fabricating the gate dielectric layer of a core device according to an embodiment of the present invention.

FIGS. 4A to 4C are schematic cross-sectional views showing the process of fabricating the gate dielectric layer of a core device according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

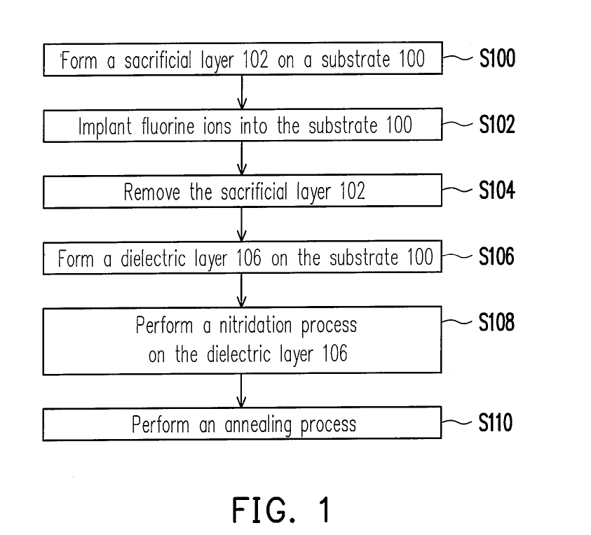

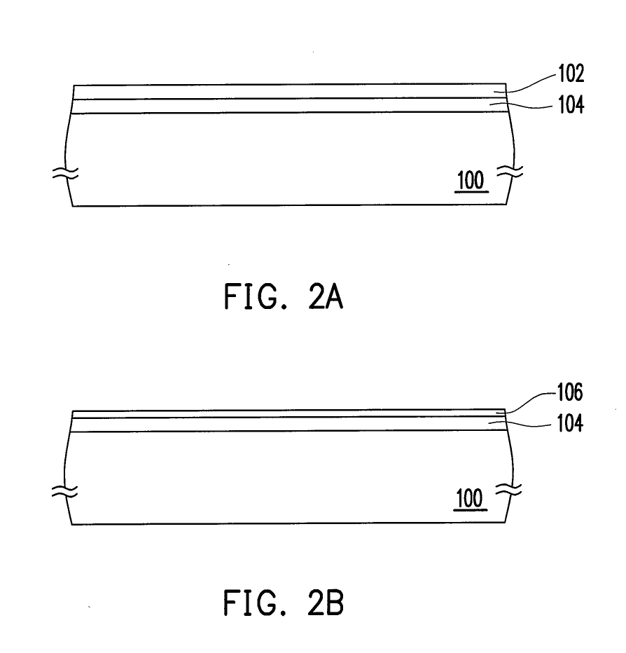

FIG. 1 is a flow diagram showing a method for fabricating a gate dielectric layer according to an embodiment of the present invention. FIGS. 2A and 2B are schematic cross-sectional views showing the process of fabricating a gate dielectric layer according to an embodiment of the present invention.

First, as shown in FIGS. 1 and 2A, the step S100 is performed to form a sacrificial layer 102 on a substrate 100. The material of the sacrificial layer 102 is silicon oxide, for example. The method of forming the sacrificial layer 102 is performing a thermal oxidation process, for example.

Next, the step S102 is performed to implant fluorine ions into the substrate 100 so as to form a doped region 104. The method of implanting fluorine ions into the substrate 100 is performing an ion implantation process, for example. With the sacrificial layer 102 covering the substrate 100, fluorine ions are prevented from directly bombarding the substrate 100 so that the damage to the surface of the substrate 100 is minimized and the sacrificial layer 102 could make the fluorine ions close to the surface of the substrate 100.

As shown in FIGS. 1 and 2B, the step S104 is performed to remove the sacrificial layer 102. The method of removing the sacrificial layer 102 is performing a wet etching process, for example.

Next, the step S106 is performed to form a dielectric layer 106 on the substrate 100. The dielectric layer 106 may serve as a gate dielectric layer. The material of the dielectric layer 106 is silicon oxide, for example. The method of forming the dielectric layer 106 is performing a thermal oxidation process, for example.

After that, the step S108 of performing a nitridation process of the dielectric layer 106 is optionally performed. The nitridation process is performing a plasma nitridation process, for example. When the material of the dielectric layer 106 is silicon oxide, the material of the dielectric layer 106 can be converted into silicon oxynitride by the nitridation process so as to adjust the dielectric constant value of the dielectric layer 106.

Thereafter, the step S110 of performing an annealing process is optionally performed. The annealing process can repair the damages to the surface of the dielectric layer 106 caused by the plasma in the nitridation process, and furthermore, can repair any dangling bonds at the interface between the dielectric layer 106 and the substrate 100.

In the foregoing embodiment, fluorine ions, which are capable of bonding with dangling silicon bonds, are implanted into the substrate 100. As a result, the interface between the dielectric layer 106 and the substrate 100 is stabilized and the threshold voltage is lowered. Moreover, the reliability of the semiconductor device is improved and the life span of the semiconductor device is prolonged.

In addition, less dangling bonds are left for trapping the charge carriers when the semiconductor device operates because the dangling bonds at the interface between the dielectric layer 106 and the substrate 100 are bonded to the fluorine ions. Consequently, the mobility of the charge carriers in the channel region is increased and hence the amount of current flowing between the source and the drain in the conductive state is enhanced.

On the other hand, the method for fabricating the gate dielectric layer according to the present invention can also be applied to fabricate the gate dielectric layer of a core device. Moreover, the method can be combined with the method for fabricating the gate dielectric layer of an input/output device. In the following, a method for fabricating the gate dielectric layer of a core device according to the present invention is described.

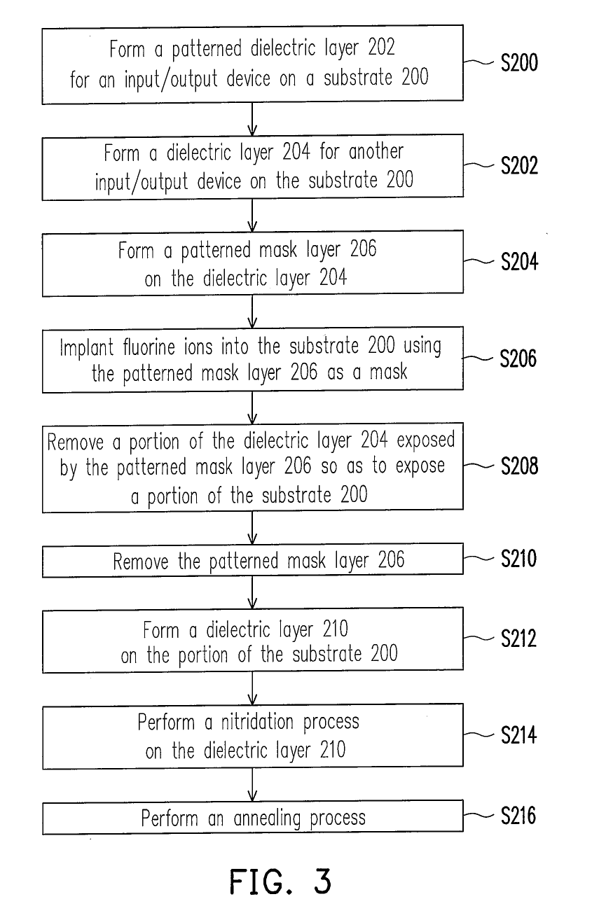

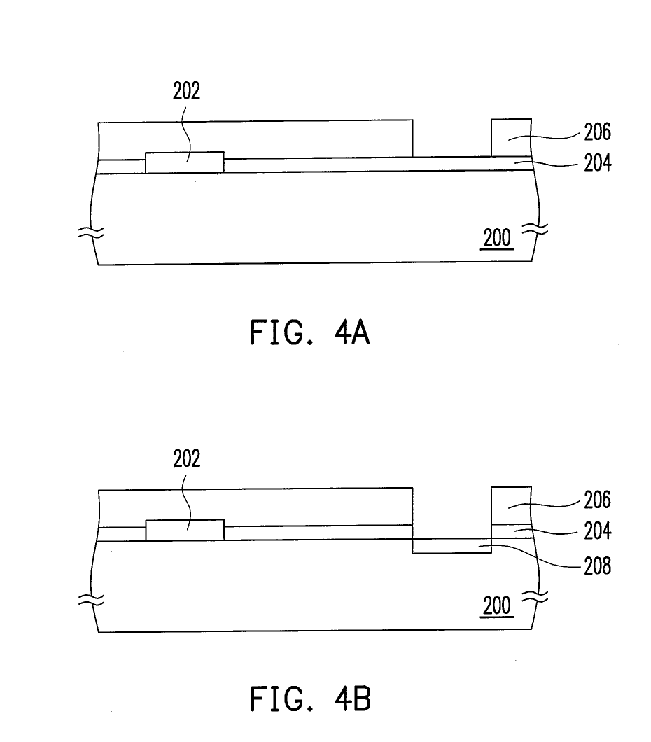

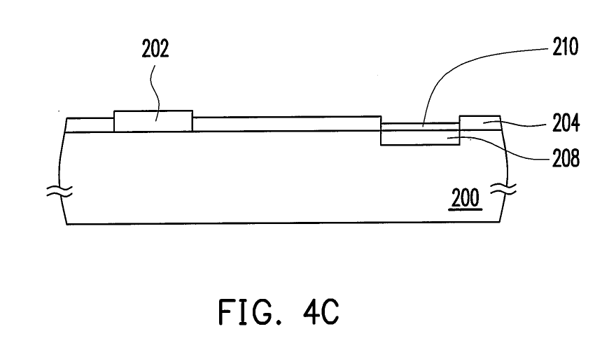

FIG. 3 is a flow diagram showing a method of fabricating the gate dielectric layer of a core device according to an embodiment of the present invention. FIGS. 4A to 4C are schematic cross-sectional views showing the process of fabricating the gate dielectric layer of a core device according to an embodiment of the present invention.

First, as shown in FIGS. 3 and 4A, the step S200 is performed to form a patterned dielectric layer 202 for a input/output device on a substrate 200. The patterned dielectric layer 202 can be used as the gate dielectric layer of the input/output device. The method of forming the patterned dielectric layer 202 is, for example, performing a thermal oxidation process to form a dielectric layer 202 on the substrate 200 and patterning the dielectric layer 202 by performing a conventional patterning process. The material of the dielectric layer 202 is silicon oxide and the method of forming the dielectric layer 202 is performing a thermal oxidation process, for example.

Next, the step S202 is performed to form a dielectric layer 204 for another input/output device on the substrate 200. The dielectric layer 204 can be used as the gate dielectric layer of the input/output device. The material of the dielectric layer 204 is silicon oxide and the method of forming the dielectric layer 204 is performing a thermal oxidation process, for example.

Next, the step S204 is performed to form a patterned mask layer 206 on the dielectric layer 204. The patterned mask layer 206 exposes the area for forming the core device. The material of the mask layer 206 is photoresist material and the method of forming the patterned mask layer 206 is performing a photolithographic process, for example.

Thereafter, as shown in FIGS. 3 and 4B, the step S206 is performed to implant fluorine ions into the substrate 200 to form a doped region 208 using the patterned mask layer 206 as a mask. The method of implanting fluorine ions into the substrate 200 is performing an ion implantation process, for example. With the dielectric layer 204 covering the substrate 200, fluorine ions are prevented from directly bombarding the substrate 200 so that the damage to the surface of the substrate 200 is minimized.

Next, the step S208 is performed to remove a portion of the dielectric layer 204 exposed by the patterned mask layer 206 so as to expose a portion of the substrate 200. The method of removing the portion of the dielectric layer 204 is performing a wet etching process, for example.

Next, as shown in FIGS. 3 and 4C, the step S210 is performed to remove the patterned mask layer 206. The method of removing the patterned mask layer 206 is performing a dry etching process, for example.

Next, the step S212 is performed to form a dielectric layer 210 on the portion of the substrate 200. The dielectric layer 210 can be used as the gate dielectric layer of the core device. The material of the dielectric layer 210 is silicon oxide and the method of forming the dielectric layer 210 is performing a thermal oxidation process, for example. In the present embodiment, the thickness of the dielectric layer 202, the dielectric layer 204 and the dielectric layer 210 are related to one another in such a way that, for example, the thickness of the dielectric layer 210 is smaller than that of the dielectric layer 204 and the thickness of the dielectric layer 204 is smaller than that of the dielectric layer 202.

Furthermore, the step S214 of performing a nitridation process is optionally performed on the dielectric layer 210. The nitridation process is a plasma nitridation process, for example. When the material of the dielectric layer 210 is silicon oxide, the material of the dielectric layer 210 can be converted into silicon oxynitride by the nitridation process so as to adjust the dielectric constant value of the dielectric layer 210.

Next, the step S216 of performing an annealing process is optionally performed. The annealing process can repair the damages to the surface of the dielectric layer 210 caused by the plasma in the nitridation process, and furthermore, can repair any dangling bonds at the interface between the dielectric layer 210 and the substrate 200.

It should be noted that the present embodiment illustrates the formation of the dielectric layer 202 and the dielectric layer 204 of the input/output devices with different thickness and the formation of the dielectric layer 210 of the core device. However, in other embodiment, there is no need to form the dielectric layer 202 and the dielectric layer 204 of the input/output devices as two layers with different thickness. Moreover, the step S200 can be eliminated according to the requirements of the process design so that no dielectric layer 202 is formed on the substrate 200.

Accordingly, the process for fabricating the dielectric layer 210 (the gate dielectric layer) of the core device and the process for fabricating the dielectric layer 202 and the dielectric layer 204 (the gate dielectric layer) of the input/output devices can be combined. Therefore, the dielectric layer 204 can be utilized to serve as a sacrificial layer for implanting fluorine ions into the substrate 200. Consequently, the complexity of the fabrication process can be reduced and the present invention is able to provide a simpler method of fabrication.

In summary, the present invention has at least the following advantages:

1. The method for fabricating the gate dielectric layer of the present invention can stabilize the interface between the gate dielectric layer and the substrate so as to lower the threshold voltage, increase the reliability and prolong the life span of the semiconductor device.

2. In the method for fabricating the gate dielectric layer of the present invention, the fluorine ions bond with the dangling bonds. Hence, the mobility of the carriers in the channel region is effectively increased. As a result, the amount of current flowing in the conductive state between the source and the drain is also increased.

3. The method for fabricating the gate dielectric layer of a core device according to the present invention can be easily combined with existing semiconductor fabrication process so as to provide a simpler fabrication process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a gate dielectric layer, comprising:
forming a sacrificial layer on a substrate;
implanting fluorine ions into the substrate;
removing the sacrificial layer; and
forming a dielectric layer on the substrate.

2. The method according to claim 1, wherein the method of forming the sacrificial layer comprises performing a thermal oxidation process.

3. The method according to claim 1, wherein the method of implanting fluorine ions into the substrate comprises performing an ion implantation process.

4. The method according to claim 1, wherein the method of forming the dielectric layer comprises performing a thermal oxidation process.

5. The method according to claim 1, wherein the method further comprises performing a nitridation process on the dielectric layer after forming the dielectric layer on the substrate.

6. The method according to claim 5, wherein the nitridation process comprises performing a plasma nitridation process.

7. The method according to claim 5, wherein the method further comprises performing an annealing process after performing a nitridation process on the dielectric layer.

8. A method for fabricating a gate dielectric layer of a core device, comprising:
forming a first dielectric layer for a first input/output device on a substrate;
forming a patterned mask layer on the first dielectric layer;
implanting fluorine ions into the substrate using the patterned mask layer as a mask;
removing a portion of the first dielectric layer exposed by the patterned mask layer so as to expose a portion of the substrate;
removing the patterned mask layer; and
forming a second dielectric layer on the portion of the substrate.

9. The method according to claim 8, wherein the method of forming the first dielectric layer comprises performing a thermal oxidation process.

10. The method according to claim 8, wherein the method of implanting fluorine ions into the substrate comprises performing an ion implantation process.

11. The method according to claim 8, wherein the method of forming the second dielectric layer comprises performing a thermal oxidation process.

12. The method according to claim 8, wherein the thickness of the second dielectric layer is smaller than the thickness of the first dielectric layer.

13. The method according to claim 8, wherein the method further comprises performing a nitridation process on the second dielectric layer after forming the second dielectric layer on the portion of the substrate.

14. The method according to claim 13, wherein the nitridation process comprises performing a plasma nitridation process.

15. The method according to claim 13, wherein the method further comprises performing an annealing process after performing the nitridation process on the second dielectric layer.

16. The method according to claim 8, wherein the method of removing the patterned mask layer comprises performing a dry etching process.

17. The method according to claim 8, wherein the method further comprises forming a patterned third dielectric layer for a second input/output device on the substrate before forming the first dielectric layer.

18. The method according to claim 17, wherein the method of forming the patterned third dielectric layer comprises:
forming a third dielectric layer on the substrate; and
patterning the third dielectric layer.

19. The method according to claim 18, wherein the method of forming the third dielectric layer comprises performing a thermal oxidation process.

20. The method according to claim 18, wherein the thickness of the first dielectric layer is smaller than the thickness of the third dielectric layer, and the thickness of the second dielectric layer is smaller than the thickness of the first dielectric layer.
